(19) United States
(12) Patent Application Publication
(10) Pub. No.: US 2022/0320015 A1
(43) Pub. Date: Oct. 6, 2022

(54) BACKSIDE STRUCTURE FOR OPTICAL ATTACK MITIGATION

(71) Applicant: GLOBALFOUNDRIES U.S. Inc., Santa Clara, CA (US)

(72) Inventors: Vibhor JAIN, Williston, VT (US); Yusheng BIAN, Ballston Lake, NY (US); Yves T. NGU, Williston, VT (US); Sunil K. SINGH, Mechanicville, NY (US); Sebastian T. VENTRONE, South Burlington, VT (US); Johnatan A. KANTAROVSKY, South Burlington, VT (US)

(21) Appl. No.: 17/223,596

(22) Filed: Apr. 6, 2021

(51) Int. Cl. H01L 23/00

(52) U.S. Cl. CPC H01L 23/573

(57) ABSTRACT

The present disclosure relates to semiconductor structures and, more particularly, to a backside structure for optical attack mitigation and methods of manufacture. The structure includes: at least one device on a front side of a semiconductor substrate; and a plurality of grating layers under the at least one device. The plurality of grating layers includes at least a first material having a first refractive index alternating with a second material having a second refractive index.

### FIELD OF THE INVENTION

The present disclosure relates to semiconductor structures and, more particularly, to a backside structure for optical attack mitigation and methods of manufacture.

### BACKGROUND

Active x-ray spectrum analysis may be used to observe an integrated circuit under power in order to determine voltage contrasts and a functional state of the design. Sophisticated schemes utilizing backside scanning electron microscope (SEM) allow even the decryption of private keys in a field programmable gate array (FPGA). Also, light from the backside of the chip may be used to scan across the die and over time capture voltages used to reconstruct the function of the chip, itself. A known technique to prevent such attacks can encompass package shielding, but this is still prone to tampering. Accordingly, known techniques have not been able to prevent uncovering of key technology and intellectual property in an integrated circuit, particularly from backside optical attacks.

### SUMMARY

In an aspect of the disclosure, a structure comprises: at least one device on a front side of a semiconductor substrate; and a plurality of grating layers under the at least one device, the plurality of grating layers comprising a first material comprising at least a first refractive index alternating with a second material comprising a second refractive index.

In an aspect of the disclosure, a structure comprises: a substrate; at least one device on a first side of the substrate; and a reflector located on a second side of the substrate, the reflector comprising a plurality of alternating materials comprising structural characteristics that reflect propagating optical waves from reaching the at least one device.

In an aspect of the disclosure, a method comprises: forming at least one device on a front side of a semiconductor substrate; and forming a plurality of grating layers under the at least one device, the plurality of grating layers comprising a first material comprising a first refractive index alternating with a second material comprising a second refractive index.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a backside structure for optical attack mitigation, amongst other features, in accordance with aspects of the present disclosure.

FIG. 2 shows a backside structure for optical attack mitigation, amongst other features, in accordance with additional aspects of the present disclosure.

FIGS. 3A-3C show fabrication processes of the structure shown in FIG. 1 in accordance with aspects of the present disclosure.

FIG. 4 shows alternative fabrication processes of the structure shown in FIG. 1 or FIG. 3C, in accordance with additional aspects of the present disclosure.

### DETAILED DESCRIPTION

The present disclosure relates to semiconductor structures and, more particularly, to a backside structure for optical attack mitigation and methods of manufacture. More specifically, the backside structure comprises a buried Bragg reflector comprising a plurality of grating layers that reflect light away from active components in an integrated circuit. Advantageously, the thickness and material of the plurality of the grating layers can be changed to cover a wide range of frequencies that may be used to protect semiconductor devices from backside optical attacks.

In embodiments, the Bragg reflector comprises a plurality of grating layers located below active devices formed on a semiconductor wafer. For example, the grating layers may be below active FETs fabricated on bulk semiconductor or semiconductor on insulator (SOI) substrates. By placing the grating layers under the active region (FETs) of an integrated circuit chip, it is possible to prevent light from reaching the active region and, hence, preventing unauthorized users from obtaining useful information concerning the functionality of the integrated circuit.

In embodiments, the grating layers may include alternating layers of materials with different dielectric constants to prevent O-band light (energy) from passing through to the active devices. For example, the grating layers may be alternating layers of Si/SiO₂ or alternating layers of Si/SiGe. The buried grating layers can also comprise different thickness or material properties. Accordingly, the buried grating layers may be used for chip security tailored to different wavelengths.

The backside structure for optical attack mitigation of the present disclosure may be manufactured in a number of ways using a number of different tools. In general, though, the methodologies and tools are used to form structures with dimensions in the micrometer and nanometer scale. The methodologies, i.e., technologies, employed to manufacture the backside structure for optical attack mitigation of the present disclosure have been adopted from integrated circuit (IC) technology. For example, the structures are built on wafers and are realized in films of material patterned by photolithographic processes on the top of a wafer. In particular, the fabrication of the backside structure for optical attack mitigation uses three basic building blocks: (i) deposition of thin films of material on a substrate, (ii) applying a patterned mask on top of the films by photolithographic imaging, and (iii) etching the films selectively to the mask.

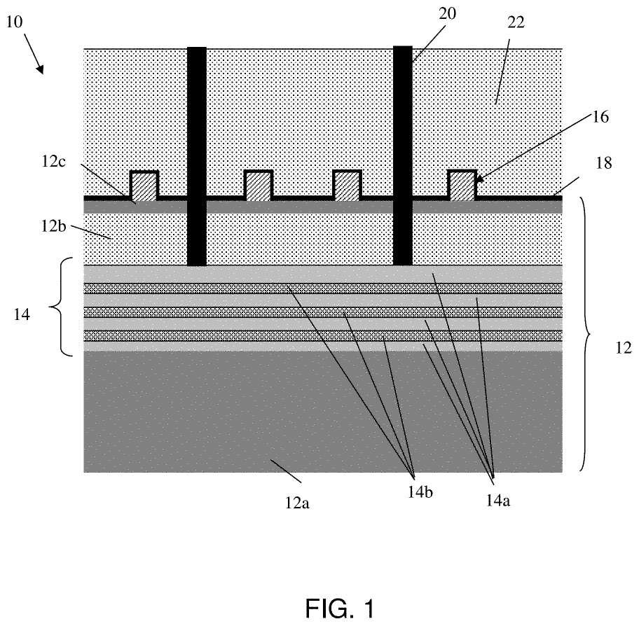

FIG. 1 shows a backside structure for optical attack mitigation, amongst other features. More specifically, the structure 10 includes an SOI substrate 12 comprising a semiconductor wafer 12a, a buried insulator layer 12b and a semiconductor material 12c over the buried insulator layer 12b. The wafer 12a and semiconductor material 12c may comprise any suitable semiconductor material including, but not limited to, Si, SiGe, SiGeC, SiC, GaAs, InAs, InP, and other III/V or II/VI compound semiconductors. The buried insulator layer 12b may comprise any suitable material, including silicon oxide, sapphire, other suitable insulating materials, and/or combinations thereof. An exemplary buried insulator layer 12b may be a buried oxide layer (BOX). The buried insulator layer 12b may be formed by any suitable process such as separation by implantation of oxygen (SIMOX), oxidation, deposition, and/or other suitable process.

Still referring to FIG. 1, a plurality of grating layers 14 may be provided below the buried insulator layer 12b and below a plurality of devices 16 formed from the semiconductor material 12c. In embodiments, the devices 16 may be active devices. For example, the devices 16 may be transistors of any known type, e.g., MOSFETs, bipolar junction transistors, etc.

Although not critical to the understanding of the present disclosure, the devices 16 may be fabricated using conventional CMOS processes. For example, in the standard CMOS processing for active device fabrication (e.g., FET), a gate dielectric and polysilicon are formed, e.g., deposited, onto the semiconductor material 12c, followed by a patterning process. An insulator material such as nitride or oxide may be deposited on the patterned materials, followed by an anisotropic etching process to form sidewalls. Additional processing may be performed such as, e.g., well implants, source/drain features, silicide processes, etc., which are well known in the art such that no further explanation is required for a complete understanding of the disclosure.

The plurality of grating layers 14 (e.g., Bragg reflector) comprise alternating layers of different materials, each of which may have one quarter wavelength thickness. In further embodiments, the layers 14a, 14b of different materials may include any odd integer multiple, including ¾ or 5/4 wavelength as illustrative examples. As each of the different layers 14a, 14b are a quarter wavelength or odd integer multiple thick, a part of the incident beam (e.g., optical wave from a backside) may be partially reflected at each interface in the stack of grating layers 14. For example, the reflected parts of the light (e.g., energy) have a phase shift of 180° as the incident light goes from a low-index medium to a high-index medium. The relative phase difference of all reflected beams may then be zero or a multiple of 360° and therefore interfere constructively. In this way, the incident light will be fully reflected away from the devices 16.

In more specific embodiments, the layers 14a, 14b may be alternating materials with varying refractive indices or dielectric constants, resulting in periodic variation in the effective refractive index. Within this range of wavelengths, light is prevented from propagating to the devices 16. For example, the alternating layers 14a, 14b may be an SiGe layer 14a and Si layer 14b. As another example, the alternating layers 14a, 14b may be an SiO₂ layer 14a and Si layer 14b. In additional embodiments, the insulator layer 14a may be composed of nitride or other dielectric materials.

In further embodiments, the layers 14a, 14b may be tuned to cover a wide range of frequencies that may be used to protect semiconductor structures from backside optical attacks. For example, the layers 14a, 14b may have different thicknesses tuned for different frequencies (or wavelengths) of light based on, e.g., material thickness=λ/4n where “n” is the refractive index of the material as defined as the ratio of the speed of light in a vacuum to the speed of light in that material. As one of skill in the art should understand, the dielectric constant of a material is proportional to the refractive index of the same material.

By way of one example, the Si layer may have a thickness of about 93 nm and the SiO₂ layer may have a thickness of about 226 nm to reflect light with a frequency of about 229 THz. In another example, the thickness of the Si layer and the SiO₂ layer may vary from the above noted thicknesses by about +/−10% while still providing adequate reflection of light with a transmission (attenuation) across an entire 0-band (e.g., wavelength between 1260 nm to 1360 nm). By way of another example, for Si/SiGe grating layers (assuming 30% Ge), the Si layer may be tuned to a thickness of approximately 93 nm and the SiGe layer may be tuned to a thickness of approximately 85 nm to reflect light with a frequency of about 229 THz.

FIG. 1 further shows a plurality of contacts 20 extending through an interlevel dielectric material 22 and an optional nitride layer 18, electrically connecting to the layer 14a (and/or 14b) of the plurality of grating layers 14. In embodiments, the contacts 20 may be located between the devices 16.

In the Si/SiGe configuration, the Si and SiGe layers may be doped to form a resistor type material. In an embodiment, the layers may be doped with p-type dopant for example boron (B) to form a p-type resistor or a n-type dopant like arsenic (As) to form a n-type resistor. In this way, the resistance of the different layers 14a, 14b may be monitored using the contacts 20 such that any attempt to remove or tamper with layer 14a (or 14b) may be detected which, in turn, may be used to trigger a tamper response. In the Si/SiO₂ configuration, the Si layer 14b may also be doped and the contacts may extend to any combination of layers 14a, 14b. In this scenario, the contacts 20 may extend to either or multiple Si layers 14b to monitor for either a change in resistance (within the layer) or a change in capacitance (between layers).

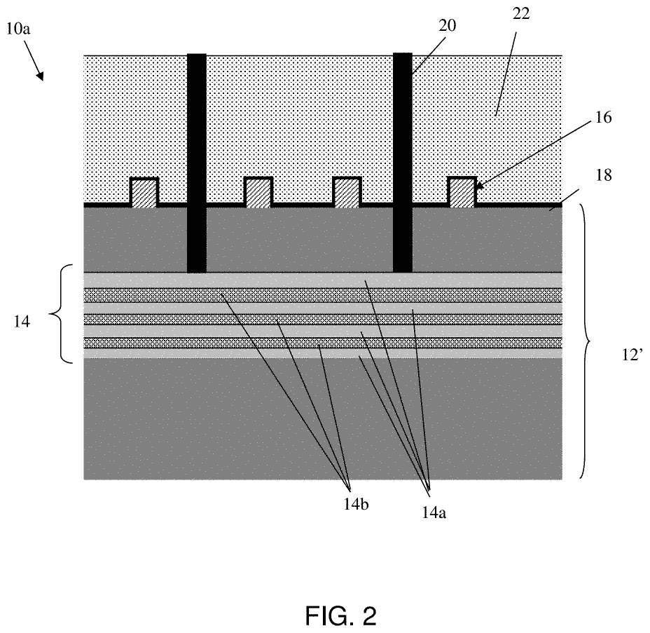

FIG. 2 shows backside structure 10a for optical attack mitigation, amongst other features, in accordance with additional aspects of the disclosure. In this embodiment, the substrate 12′ comprises a bulk substrate composed of any suitable semiconductor material including, but not limited to, Si, SiGe, SiGeC, SiC, GaAs, InAs, InP, and other III/V or II/VI compound semiconductors. The plurality of grating layers 14 may be embedded within the bulk substrate 12′, below the plurality of devices 16 as described with respect to FIG. 1.

As already described herein, the plurality of grating layers 14 comprise alternating layers 14a, 14b, each of which have one quarter or odd integer multiple wavelength thickness. In more specific embodiments, the alternating layers 14a, 14b comprise, e.g., a material comprising a high dielectric constant alternating with a material comprising a lower dielectric constant (e.g., alternating high and low index films). In even more specific embodiments, the alternating layers may be a layer of SiGe 14a and a layer of Si 14b, each of which may be formed on the bulk substrate 12′. Alternatively, the alternating layers 14a, 14b may be a layer of SiO₂ and a layer of Si. These layers 14a, 14b may also be tuned to cover a wide range of frequencies used to protect semiconductor structures from backside optical attacks as already described herein.

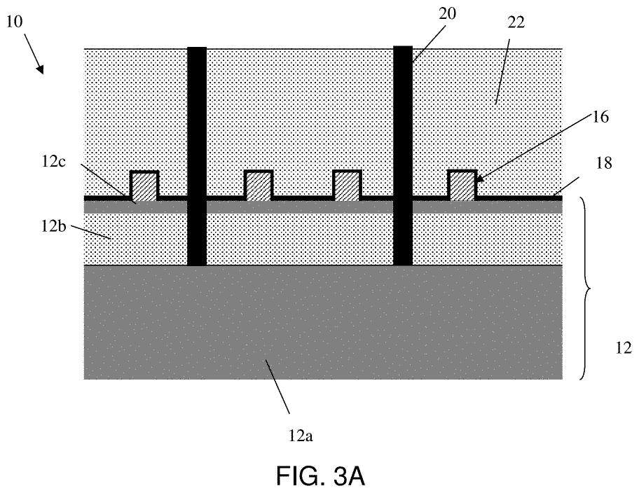

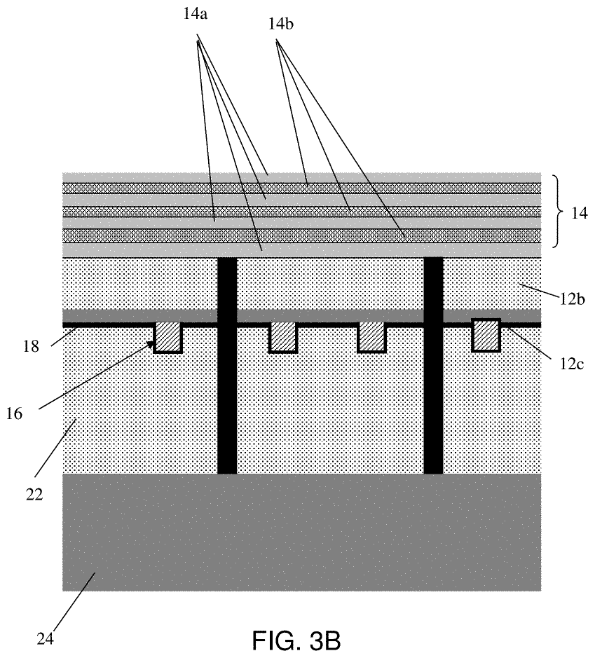

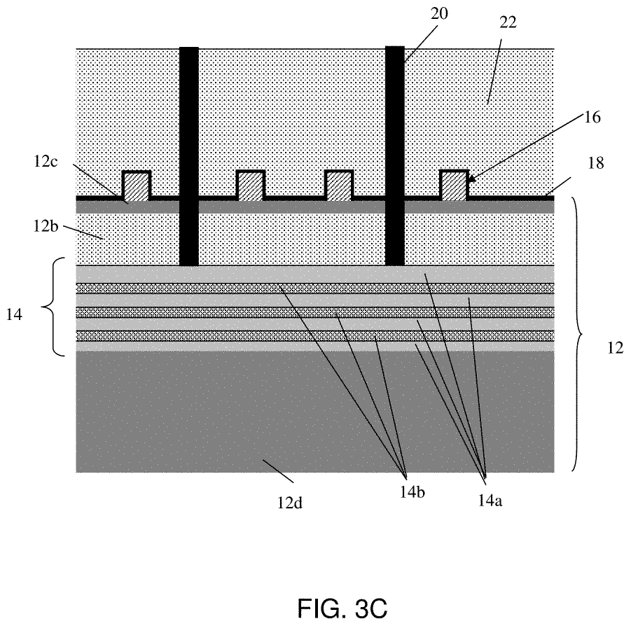

In embodiments, the alternating layers of SiGe and Si may be fabricated using conventional epitaxial growth processes, e.g., molecular beam epitaxy (MBE) or chemical vapor deposition (CVD), followed by another epitaxial growth process of the bulk substrate 12′ on the topmost layer of the layers 14a, 14b. In embodiments, the alternating layers of SiGe and Si may be doped during the growth process or subjected to an implantation process. The bulk substrate 12′ should be of sufficient thickness to ensure that the grating layers 14a, 14b do not interfere with any logic, e.g., devices 16. Following the formation of the upper portion the bulk substrate 12′, standard front end of the line (FEOL) CMOS processes may be used to form the devices 16 and standard back end of the line (BEOL) CMOS processes may be used to form the contacts 20, etc. In embodiments, for bulk substrate applications, the stack should either be Si/SiGe or a layer transfer process should be implemented to form the buried stack as shown in FIGS. 3A-3C.

FIG. 2 further shows a plurality of contacts 20 extending through an interlevel dielectric material 22 and an optional nitride layer 18, contacting the layer 14a (and/or 14b) of the plurality of grating layers 14. In this way, the contacts 20 may contact layers 14a, 14b, which may be monitored for either a change in resistance (within the layer) or a change in capacitance (between Si layers) to determine if there is any tampering of such materials and, hence, to trigger a tamper response.

FIGS. 3A-3C show fabrication processes of the structure 10 shown in FIG. 1. More specifically, FIG. 3A shows the devices 16 formed on the SOI wafer 12 using conventional front end of the line (FEOL) processes as is known in the art such that no further explanation is required for a complete understanding of the disclosure.

The contacts 20 are formed through the interlevel dielectric material 22 and buried insulator material 12b, reaching to the wafer 12a. In embodiments, the contacts 20 may be formed using conventional thru silicon via technologies including, e.g., conventional lithography, etching and deposition methods known to those of skill in the art. For example, a resist formed over the interlevel dielectric material 22 is exposed to energy (light) to form a pattern (opening). An etching process with a selective chemistry, e.g., reactive ion etching (RIE), will be used to form one or more trenches in the insulator material 20 through the openings of the resist. The resist may then be removed by a conventional oxygen ashing process or other known stripants. Following the resist removal, conductive material may be deposited by any conventional deposition processes, e.g., chemical vapor deposition (CVD) processes. Any residual material on the surface of the insulator material 18 may be removed by conventional chemical mechanical polishing (CMP) processes.

In FIG. 3B, the structure of FIG. 1 is flipped over and a temporary handle wafer 24 is bonded to a front side of the structure. In embodiments, the handle wafer 24 may be bonded using an oxide-oxide bonding techniques as one illustrative example. The wafer 12a is then removed using conventional etchants, e.g., dilute aqueous HF etch solution, e.g., Nitric acid (HNO₃)+hydrofluoric acid (HF), or grinding processes. The grating layers 14a, 14b may be formed on the exposed buried insulator layer 12b in successive deposition processes. In FIG. 3C, the handle wafer 24 may be removed and a wafer 12d will replace the original wafer 12a of FIG. 3A.

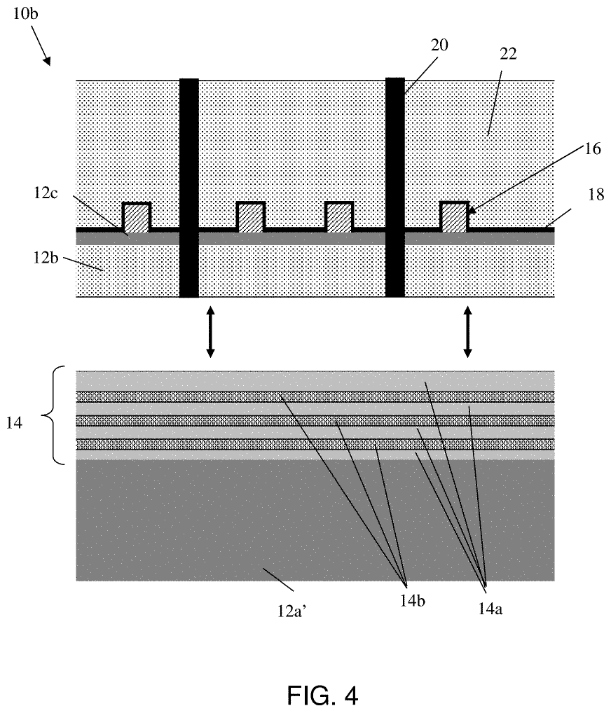

FIG. 4 shows fabrication processes of the structure shown in FIG. 1 or 3C, in accordance with additional aspects of the present disclosure. In the structure 10b and respective fabrication processes, the layers 14a, 14b may be formed on a bulk wafer 12a′, followed by attaching a topmost grating layer, e.g., layer 14a, to a buried insulator material 12b as shown by the arrows. In embodiments, the layers 14a, 14b may be alternating Si/SiGe material formed (e.g., deposited) using CVD or MBE processes as already described herein. The topmost grating layer, e.g., layer 14a, may be bonded to the buried insulator material 12b using, for example, an oxide or other known bonding technique such that no explanation is required herein for a complete understanding of the present disclosure. In this way, the combination of the bulk wafer 12a′, the buried insulator material 12b and the semiconductor layer 12c will form an SOI implementation, with the grating layers 14a, 14b buried between the bulk wafer 12a′ and the buried insulator material 12b as shown, for example, in FIG. 3C.

The backside structure for optical attack mitigation may be utilized in system on chip (SoC) technology. It should be understood by those of skill in the art that SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also commonly used in embedded systems and the Internet of Things.

The method(s) as described above is used in the fabrication of integrated circuit chips. The resulting integrated circuit chips may be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product may be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
at least one device on a front side of a semiconductor substrate; and
a plurality of grating layers under the at least one device, the plurality of grating layers comprising at least a first material comprising a first refractive index alternating with a second material comprising a second refractive index.

2. The structure of claim 1, wherein each layer of the plurality of grating layers comprises any odd integer multiple wavelength thickness.

3. The structure of claim 1, wherein the first material comprises a first dielectric constant and the second material comprises a second dielectric constant different from the first dielectric constant.

4. The structure of claim 1, wherein a combination of the plurality of grating layers reflect light away from the at least one device.

5. The structure of claim 1, wherein the first material comprises SiGe and the second material comprises Si.

6. The structure of claim 5, wherein the first material and the second material comprise doped materials.

7. The structure of claim 1, wherein the first material comprises insulator material and the second material comprises doped semiconductor material.

8. The structure of claim 1, further comprising contacts electrically connecting to at least one of the first material and the second material.

9. The structure of claim 1, wherein the semiconductor substrate comprises a bulk substrate and the plurality of grating layers are embedded within the bulk substrate, below the at least one device.

10. The structure of claim 1, wherein the semiconductor substrate comprises a semiconductor on insulator (SOI) substrate, a topmost layer of the plurality of grating layers contacts an underside of an insulator layer of the SOI substrate and a bottom most layer of the plurality of grating layers contacts a top surface of a semiconductor substrate of the SOI substrate.

11. A structure comprising:
a substrate;
at least one device on a first side of the substrate; and
a reflector located on a second side of the substrate, the reflector comprising a plurality of alternating materials comprising structural characteristics that reflect propagating optical waves from reaching the at least one device.

12. The structure of claim 11, wherein the plurality of alternating materials includes a stack of materials alternating between a high dielectric constant material and a lower dielectric constant material.

13. The structure of claim 12, wherein each layer of the plurality of alternating materials comprises an odd multiple wavelength thickness.

14. The structure of claim 11, wherein the plurality of alternating materials comprises SiGe alternating with Si.

15. The structure of claim 11, wherein the plurality of alternating materials comprises insulator material alternating with doped semiconductor material.

16. The structure of claim 11, further comprising contacts electrically connecting to at least one of the plurality of alternating materials.

17. The structure of claim 11, wherein the substrate comprises a bulk substrate and the plurality of alternating materials are embedded within the bulk substrate, below the at least one device.

18. The structure of claim 11, wherein the substrate comprises a semiconductor on insulator (SOI) substrate, a topmost layer of the plurality of alternating materials contacts an insulator layer of the SOI substrate and a bottom most layer of the plurality of alternating materials contacts a semiconductor substrate of the SOI substrate.

19. The structure of claim 11, wherein the plurality of alternating materials comprise grating layers.

20. A method comprising:
forming at least one device on a front side of a semiconductor substrate; and
forming a plurality of grating layers under the at least one device, the plurality of grating layers comprising a first material comprising a first refractive index alternating with a second material comprising a second refractive index.
